(19) United States
(12) Patent Application Publication
(10) Pub. No.: US 2010/0288353 A1
(43) Pub. Date: Nov. 18, 2010

(54) Coextruded, biaxially oriented polyester films with improved adhesion properties, reverse-side laminates for solar modules, and solar modules

(76) Inventors: Holger KLIESCH, Ginsheim-Gustavsburg (DE); Herbert Peiffer, Mainz (DE); Lothar Bothe, Mainz (DE)

Correspondence Address: PROPAT, L.L.C., 425-C SOUTH SHARON AMITY ROAD, CHARLOTTE, NC, 28211-2841, US

(21) Appl. No.: 12/778,193

(22) Filed: May 12, 2010

(30) Foreign Application Priority Data
May 18, 2009 (DE) 10 2009 021 712.6

(51) Int. Cl. H01L 31/0216; B32B 27/30; B32B 37/16

(52) U.S. Cl. 136/256; 428/515; 156/164

(57) ABSTRACT

The invention relates to a coextruded, biaxially oriented polyester film including a base layer (B) and at least one outer layer (A), in which the base layer (B) is mainly formed from thermoplastic polyester and the outer layer (A) is mainly formed from a mixture of from 50 to 97% by weight of ethylene-acrylate copolymer and from 3 to 50% by weight of polyester, where the proportion of acrylate in the ethylene-acrylate copolymer is from 2.5 to 15 mol %, based on the monomers of the copolymer. A process for the production of the film, and the use of the film are also described.

### CROSS-REFERENCE TO RELATED APPLICATIONS

This application claims priority to German Patent Application 10 2009 021 712.6 filed May 18, 2009 which is hereby incorporated herein by reference in its entirety.

### FIELD OF THE INVENTION

The invention relates to coextruded, biaxially oriented polyester films with improved adhesion properties, to reverse-side laminates for solar modules comprising the coextruded, biaxially oriented polyester films, and to the solar modules themselves. The invention in particular relates to coextruded, biaxially oriented polyester films which have very good adhesion to ethylene-vinyl acetate copolymers (EVA copolymers), which are used as a means of encapsulation in solar cells, the inventive films having at least one coextruded outer layer that has a specific constitution. The invention further relates to a film laminate for providing reverse-side protection to solar modules comprising the films of the invention with very good adhesion to the EVA encapsulation material of the solar cells, and to the solar cells themselves.

### BACKGROUND OF THE INVENTION

Photovoltaic modules or solar modules serve to generate electrical energy from sunlight, and are comprised of a laminate which comprises, as core layer, a solar-cell system, e.g. silicon solar cells. These silicon solar cells have low mechanical strength, however, and therefore require protection. Encapsulation material, usually comprised of crosslinked EVA, encapsulates the solar cells in order to provide protection from the effects of mechanical loads and of weathering. These photovoltaic modules are generally comprised of a frontal layer made of a material with high permeability to light, this layer generally being comprised of glass, of the solar cells, surrounded by the embedding means, and of a reverse-side protective film or a reverse-side protective film laminate, known as the backsheet, which serves for protection from the effects of mechanical load and of weathering, and for electrical insulation.

The fronts used for solar modules generally comprise layers with high permeability to light, in particular low-iron-content glass with maximum permeability to light in the range from 380 to 1200 nm, and the external layer of these is also often given a surface structure as a result of chemical treatment with H₂SiF₆, in order to achieve a further increase in permeability to light. The properties of the ethylene-vinyl acetate copolymers (solar-cell encapsulation) are improved by modification with additives, e.g. soluble UV stabilizers (e.g. TINUVIN® 770) and light stabilizers (e.g. NAUGARD® P). The ethylene-vinyl acetate copolymers also comprise crosslinking agents, in particular of peroxidic type (e.g. LUPERSOL® 101; Lupersol TBEC), in order to crosslink the ethylene-vinyl acetate during the lamination step. A description of the use of EVA as encapsulation material for solar cells is found by way of example in “Application of Ethylene Vinyl Acetate as an Encapsulation Material for Terrestrial Photovoltaic Modules” (JPL Publication 83-85, Apr. 15, 1983), and in U.S. Pat. No. 6,093,757.

WO-A-94/29106, WO-A-01/67523, (whose United States equivalent is U.S. Patent Application Publication No. US 2003/029493A1) WO-A-00/02257, (whose United States equivalent is U.S. Pat. No. 6,369,316B1) and WO 2007/009140 (whose United States equivalent is U.S. Patent Application Publication No. US 2009/151774A1) disclose processes for the production of solar modules, and disclose the encapsulation of photovoltaic cells. Said processes are lamination processes, in particular vacuum-lamination processes.

A wide variety of structures has previously been proposed for reverse-side films or reverse-side laminates for photovoltaic modules. By way of example, “Performance of Encapsulating Systems” (19th European Photovoltaic Solar Energy Conference, Jun. 11, 2004, Paris, France, pages 2153-2155), EP-A-1 930 953, (whose United States equivalent is U.S. Patent Application Publication No. 2009/139564A1) or WO-A-00/74935 (whose United States equivalent is U.S. Pat. No. 6,319,596B1) provides proposals for reverse-side laminates.

The use of biaxially oriented polyester films is recommended in many structures proposed. By virtue of the orientation, biaxially oriented polyester films feature excellent mechanical properties, heat resistance, low permeability to water vapor, and good electrical insulation properties. However, the polarity, and high crystallinity of biaxially oriented polyester films give them unsatisfactory adhesion to the EVA encapsulation material of the solar cells.

If biaxially oriented polyester films are directly laminated to the embedding material of the solar cells, the adhesions, including long-term adhesions, achieved are unsatisfactory, as described by way of example in “Performance of Encapsulating Systems” (19th European Photovoltaic Solar Energy Conference, Jun. 1-11, 2004, Paris, France) and EP-A-1 826 826. (whose United States equivalent is U.S. Patent Application Publication No. US 2008/050583A1)

EP-A-1 826 826 therefore proposes, for improving the adhesion properties of biaxially oriented polyester films with respect to the embedding material, providing the surface of the polyester films with specific adhesion-promoter coatings, applied during polyester film production, after the first stretching process, and comprised of specific copolyesters and/or acrylates, which are crosslinked by a crosslinking agent. However, the proposals in EP-A-1 826 826 are still not satisfactory. The necessary additional coating step makes the production of those films complicated. Further, the crosslinking of the coating leads to difficulties in the regrind production of (or recycling of) the films, and in reuse of the film regrind in the film production process. Reuse of the film regrind in the film production process leads to discoloration of, and fisheyes in, the film. The proposed in-line application of the adhesion-promoter layer is moreover complicated and expensive. Firstly, a specific coating system is necessary for the coating process. Secondly, a solvent has to be evaporated, and additional control cost is incurred for assessing the quality of the coating. Known in-line-coating processes moreover have difficulty in applying relatively large layer thicknesses under cost-effective conditions. Realistic layer thicknesses here are generally below 0.4 μm and indeed are below 0.1 μm when using normal machine speeds and application weights (see EP-A-1 826 826, examples). However, thicker layers would be desirable for achieving stable adhesion throughout the service life of the module.

### SUMMARY OF ADVANTAGEOUS EMBODIMENTS OF THE INVENTION

It is therefore an object to provide a biaxially oriented polyester film for reverse-side laminates for photovoltaic modules, where this film has improved adhesion to the EVA encapsulation material and is easy to produce, and there is no difficulty in using the regrind from the film.

This object is achieved via a coextruded, biaxially oriented polyester film which is comprised of a base layer and of at least one coextruded surface layer, and which has not only good adhesion to the base layer but also very good initial adhesion and also long-term adhesion with respect to EVA.

### BRIEF DESCRIPTION OF THE DRAWINGS

FIG. 1 schematically illustrates an exemplary solar module structure incorporating the inventive film.

### DETAILED DESCRIPTION OF ADVANTAGEOUS EMBODIMENTS OF THE INVENTION

The coextruded, biaxially oriented polyester film comprises a base layer (B) and at least one outer layer (A), where
(a) the base layer (B) is mainly comprised of thermoplastic polyester and
(b) the outer layer (A) with good adhesion to EVA is mainly comprised of a mixture of from 50 to 97% by weight of ethylene-acrylate copolymer and from 3 to 50% by weight of polyester,
   where the proportion of acrylate in the ethylene-acrylate copolymer is from 2.5 to 15 mol %, based on the monomers of the copolymer.

The film of the invention is used directly as backsheet, or as constituent of a backsheet laminate, for a solar module, where the outer layer (A) is then in contact with the encapsulation material of the solar cells and brings about good adhesion (i.e. both initial adhesion and long-term adhesion) to the EVA encapsulation material of the solar cells.

The structure of the coextruded, biaxially oriented polyester film of the present invention comprises at least two layers. The film is then comprised of the base layer (B) and of the outer layer (A), applied by coextrusion to the base layer, and having very good adhesion to EVA, in particular to crosslinked EVA, and likewise having very good adhesion to the base layer (B). In one particular embodiment, the structure of the film has three or more layers. In the case of the three-layer structure, this is comprised of the base layer (B), of the outer layer (A), and of a further outer layer (C) arranged opposite to the outer layer (A). In the case of a four- or five-layered embodiment, the film also comprises intermediate layers between the base layer (B) and the outer layer (A) and/or (C).

The base layer (B) is comprised of at least 65% by weight, preferably at least 80% by weight, and particularly preferably at least 85% by weight, of thermoplastic polyester. The thermoplastic polyester contains aromatic dicarboxylic acids, in particular terephthalic acid, isophthalic acid, and naphthalenedicarboxylic acid, and also aliphatic diols, e.g. ethylene glycol, diethylene glycol, and butanediol. The thermoplastic polyesters can also be copolyesters. Particular mention may be made of copolyesters based on terephthalic acid and isophthalic acid in combination with preferably ethylene glycol as diol component. Particularly preferred thermoplastic polyesters are polyethylene terephthalate (PET), polyethylene naphthalate (PEN), and copolymers of ethylene terephthalate and ethylene isophthalate preferably having from 3 to 15% by weight of ethylene isophthalate content, and very particular preference is given here to polymers having at least 90% by weight of polyethylene terephthalate (based on polymer content), preferably at least 95% by weight, and in particular 98% by weight. The intrinsic viscosity (IV) of the polyethylene terephthalate of the base layer is greater than 0.5, preferably greater than 0.6, particularly preferably from 0.65 to 0.85.

Up to 35% by weight, preferably up to 20% by weight, and particularly preferably up to 15% by weight, of conventional additives, based on the weight of the base layer (B), can be added to the base layer (B). Examples of conventional additives are inorganic and organic particles, dyes, and color pigments, incompatible polymers, stabilizers, e.g. UV stabilizers, hydrolysis stabilizers, processing stabilizers, flame retardants, and chain extenders.

The inorganic and organic particles can serve to improve winding properties and further-processing properties, and/or the processing performance of the film during solar module production. Examples of particles that may be mentioned are SiO₂, kaolin, CaCO₃, and crosslinked polystyrene particles. The average particle diameter is preferably from 0.05 to 10 μm. The polyester can have coloration due to addition of dyes and color pigments. For improvement of light-reflection properties, with the aim of improving the electrical yield of the solar cell, it is particularly advantageous to add white pigments, such as BaSO₄ and TiO₂, and in particular to add TiO₂, in amounts of from 1 to 25% by weight. Particular preference is given to addition of TiO₂ when the TiO₂ has been inorganically and/or organically coated. Addition of the TiO₂ firstly brings about the white coloration of the film and, by virtue of increased reflection of light, increases the electrical yield when the film is used for backsheets of solar modules, and it secondly improves UV resistance of the film or of the backsheet, this being a particular advantage in the outdoor use of the solar module. The inorganic coating reduces the catalytically active surface area of the TiO₂ which can cause yellowing of the film, while the organic coating has a favorable effect on incorporation of the TiO₂ into the thermoplastic polyester. The median particle diameter d₅₀ of the TiO₂ is preferably in the range from 0.1 to 0.5 μm, particularly preferably from 0.15 to 0.3 μm. The amount added of the TiO₂ is preferably from 3 to 25% by weight, particularly preferably from 4 to 12% by weight, with particular preference from 5 to 10% by weight.

In order to improve long-term stability, a hydrolysis stabilizer can be added to one or more layers of the film. It is preferable to add from 0.5 to 15% by weight of hydrolysis stabilizer, particularly from 2 to 6% by weight. Preferred hydrolysis stabilizers here are epoxidized fatty acid esters such as are described in EP-A-1 634 914, (whose United States equivalent is U.S. Patent Application Publication No. US 2006/057409A1) or EP-A-1 639 915(whose United States equivalent is U.S. Patent Application Publication No. US 2006/021917A1).

Another preferred possibility, alongside the addition of hydrolysis stabilizers, is use of a polyester having low carboxy end group content (CEG)<20 mmol/kg, or particularly preferably having a carboxy end group content <12 mmol/kg (measured as stated in EP-A-0 738 749, whose United States equivalent is U.S. Pat. No. 6,020,056), with the aim of improving the hydrolysis resistance of the film itself Polymers of this type are commercially available or can be produced by known processes.

The base layer (B) can comprise up to 25% by weight, preferably up to 10% by weight, and particularly preferably up to 7% by weight, of ethylene-acrylate copolymer. The base layer (B) can preferably comprise at least 1% by weight, and particularly preferably at least 2% by weight, of ethylene-acrylate copolymer since this improves the adhesion of the outer layer (A) on the base layer (B). It is preferable that the content of ethylene acrylate copolymer here derives from film regrind.

The additives can be added to the polyester of the base layer (B) during the production process or, for example, introduced by means of masterbatch technology during film production.

In order to achieve the desired adhesion properties with respect to EVA and with respect to the base layer (B), the outer layer (A) applied via coextrusion is comprised of at least 75% by weight, preferably at least 85% by weight, and particularly preferably at least 95% by weight, of a blend of from 50 to 97% by weight of ethylene-acrylate copolymer and from 50 to 3% by weight of polyester, and up to 25% by weight of additives. The polymer blend of the outer layer (A) is comprised of at least 50% by weight, preferably of at least 60% by weight, particularly preferably of at least 75% by weight, of ethylene-acrylate copolymer. The maximum ethylene-acrylate copolymer content of the polymer blend of the outer layer (A) is 97% by weight, preferably 90% by weight.

If the content of ethylene-acrylate copolymer in the polymer blend is less than 50% by weight, the adhesion properties with respect to EVA are unsatisfactory. If the content of ethylene-acrylate copolymer is more than 97% by weight, the adhesion with respect to the base layer (B) is unsatisfactory.

Ethylene-acrylate copolymer is a copolymer comprised of ethylene and of one or more acrylate units. Examples of suitable acrylates are ethyl acrylate, ethyl methacrylate, methyl acrylate, methyl methacrylate, propyl acrylate, propyl methacrylate, isopropyl acrylate, isopropyl methacrylate, n-butyl acrylate, n-butyl methacrylate, isobutyl acrylate, isobutyl methacrylate, tert-butyl acrylate, tert-butyl methacrylate, n-hexyl acrylate, n-hexyl methacrylate, n-octyl acrylate, n-octyl methacrylate, 2-octyl acrylate, 2-octyl methacrylate, undecyl acrylate, undecyl methacrylate, octadecyl acrylate, octadecyl methacrylate, dodecyl acrylate, dodecyl methacrylate, 2-ethylhexyl acrylate, 2-ethylhexyl methacrylate isobornyl acrylate, isobornyl methacrylate, cyclohexyl acrylate, cyclohexyl methacrylate, 2-hydroxyethyl acrylate, 2-hydroxyethyl methacrylate, where preference is given to those copolymers comprising acrylates selected from methyl acrylate, ethyl acrylate, butyl acrylate, 2-ethylhexyl acrylate, and combinations of these; ethylene-methacrylate and ethylene-butyl acrylate are particularly preferred, and ethylene-methacrylate is used with very particular preference.

The content of acrylate in the ethylene-acrylate copolymer is from 2.5 to of %, preferably from 3 to 12 mol %, and particularly preferably from 5 to 11 mol %.

The melt index (2.16 kg/190° C.) of the ethylene-acrylate copolymers used in the invention (measured to DIN EN ISO 1133) is preferably in the range from 0.5 to 50 g/10 min, particularly preferably in the range from 2 to 35 g/10 min, very particularly preferably in the range from 4 to 12 g/10 min.

The ethylene-acrylate copolymers used in the invention are commercially available (examples being the following grades: LOTRYL® MA, Lotryl BA, or LOTRYL® EH from Arkema, Colombes, France, or EMAC®, or EBAC® from Westlake, Houston, USA) or can readily be produced via polymerization processes familiar to the person skilled in the art.

The polymer blend of the outer layer (A) in the invention comprises, alongside the ethylene acrylate copolymer described in some detail above, an amount in the range from 3 to 50% by weight, preferably from 5 to 40% by weight, and particularly preferably from 10 to 25% by weight, of a polyester. If the content of polyester is below 3% by weight, the adhesion to the base layer (B) is unsatisfactory. If the content is above 50% by weight, the adhesion to EVA is unsatisfactory.

The type of polyester selected here is preferably the same as that previously used for the base layer (B). The polyester content in the outer layer (A) moreover has a favorable effect on the ease of production of the film. For example, the addition of polyester reduces the tendency of the outer layer (A) to adhere to the heated metallic rolls usually used in the film-production process, and this is extremely desirable.

The outer layer (A) can comprise up to 25% by weight of additives usually used for modifying polyester. Examples of the additives are antiblocking agents, waxes, stabilizers, e.g. flame retardants, UV stabilizers, hydrolysis stabilizers, and dyes or color pigments, and the color pigments here are particularly preferably white pigments, such as BaSO₄ and TiO₂.

It is possible to add waxes in order to reduce the tendency of the outer layer (A) to adhere to metallic rolls. Amide waxes are a particularly suitable wax addition, and among these in particular N,N′-ethylenebisolearnide and N,N′-ethylenebisstearamide. The amount of wax added is preferably from 0.5 to 3% by weight, in particular from 1 to 2% by weight.

Addition of white pigments, such as BaSO₄ and TiO₂, to the outer layer (A) is advantageous when the intention is to improve the light-reflection properties of the film, with the aim of increasing the electrical yield of the solar module. It is particularly advantageous to add amounts of from 3 to 25% by weight of white pigment, but as the content of white pigment rises the adhesion with respect to the EVA falls, and the content of white pigment should therefore be 20% by weight. Addition of TiO₂, in particular in the form of rutile, is particularly advantageous, and especially advantageous when the TiO₂ has been inorganically and/or organically coated. Addition of the TiO₂ firstly brings about the white coloration of the film and, by virtue of increased reflection of light, increases the electrical yield when the film is used for backsheets of solar modules, and it secondly improves UV resistance of the film or of the backsheet, this being a particular advantage in the outdoor use of the solar module. The inorganic coating reduces the catalytically active surface area of the TiO₂ which can cause yellowing of the film, while the organic coating has a favorable effect on incorporation of the TiO₂ into the outer layer polymer mixture. The median particle diameter d₅₀ of the TiO₂ is preferably in the range from 0.1 to 0.5 μm, particularly preferably from 0.15 to 0.3 tun. The amount added of the TiO₂ is preferably from 3 to 20% by weight, particularly preferably from 4 to 12% by weight, with particular preference from 5 to 10% by weight.

The invention also provides a process for the production of the polyester film of the invention by the production process known from the literature for coextruded, biaxially oriented polyester films (e.g. “Polyesters, Films” chapter in “Encyclopedia of Polymer Science and Engineering”, vol. 12, John Wiley & Sons, 1988).

The procedure for the purposes of said process is that the melts corresponding to the film are coextruded through a flat-film die, the resultant coextruded film is applied to one or more cooled rolls for solidification, the film is then biaxially stretched (oriented), and the biaxially stretched film is heat-set and, if appropriate, also corona- or flame-treated on a surface layer intended for treatment, and is cooled and wound up.

Although one of the advantages of the present invention is that EVA-adhesion is not effected by way of any in-line coating, the film of the invention can nevertheless be coated by the in-line or off-line process—insofar as this is considered necessary for other reasons. By way of example of a procedure for further modification of the properties of the film, a known coating (e.g. for improving adhesion properties, this being advantageous in lamination applications) can be provided on that surface of the film that is opposite to the (A) layer.

The process begins, as is conventional in the extrusion process, with compressing and plastifying the polymer or polymer mixture for the individual layers of the film, in each case in an extruder, and by this stage any additives intended for addition can be present in the polymer or in the polymer mixture. If single-screw extruders are used, the raw materials should be conventionally predried, in order to inhibit any undesired hydrolytic degradation of the raw materials for the polyester during the extrusion process. If the equipment known as a twin-screw extruder is used, with devolatilization, it is generally possible to omit predrying. The use of twin-screw extruders with devolatilization is therefore particularly cost-effective, and preferred. In this case it is possible to add up to 75% by weight of film regrind to the base layer. The temperatures of the melt streams here are minimized, in order to improve the hydrolysis properties of the polymers. The melt temperature of the base layer here is therefore preferably always below 305° C., and particularly preferably below 295° C., and in particular below 285° C. The maximum melt temperature in the extruder and melt line during extrusion of the A layer is preferably below 285° C. and particularly preferably below 275° C., and ideally below 270° C. The melts are combined and then simultaneously forced through a flat-film die (slot die), and the extruded melt is applied to one or more cooled take-off rolls, whereupon the melt cools and solidifies to give a prefilm.

The biaxial stretching (orientation) process can take place simultaneously, e.g. with the use of a simultaneous stretching frame, or sequentially, e.g. with the aid of the sequential stretching process. An advantage of the simultaneous stretching process is that it is contactless, with advantages in the orientation of films with tacky surfaces. Process conditions for the production of simultaneously oriented polyester films are stated by way of example in EP-A-1 207 035, (whose United States equivalent is U.S. Patent Application Publication No. US 2002/155268A1) EP-A-1 529 799, (whose United States equivalent is U.S. Patent Application Publication No. US 2005/121822A1) or U.S. Pat. No. 6,685,865.

The temperature for the simultaneous orientation process can vary widely. Preference is generally given to the temperature range from 70 to 140° C., where the degree of stretching in the machine direction is in the range from 2.0 to 5.5:1, preferably from 3 to 4:1, and the degree of stretching perpendicular to the machine direction is preferably in the range from 2.5 to 5:1, preferably from 3 to 4.5:1.

In the sequential stretching process, the prefilm is preferably first stretched longitudinally (i.e. in machine direction=MD) and then stretched transversely (i.e. perpendicularly to the machine direction=TD). The longitudinal stretching can be carried out with the aid of two rolls rotating at different speeds corresponding to the desired stretching ratio. In the longitudinal stretching process, it is advantageous to guide the film in such a way that the film surface in contact with the surfaces of the stretching rolls rotating at different speeds is the surface facing away from the (A) layer. An even more advantageous method for the longitudinal stretching of the films of the invention is tangential stretching, described by way of example in the “Polyesters, Films” chapter in “Encyclopedia of Polymer Science and Engineering” (vol. 12, John Wiley & Sons, 1988). The method of guiding the film here is selected in such a way that the surface of the outer layer (A) is not in contact with the slow and fast-running stretching rolls, thus permitting avoidance of any possible adhesion of the film on the stretching rolls.

For the transverse stretching process, in the case of sequential stretching, an appropriate tenter frame is generally used, in which the two edges of the film are clamped, and the film is preheated and then oriented toward the two sides at an elevated temperature.

The temperatures at which the sequential biaxial stretching process is carried out depend in particular, in the case of the longitudinal stretching process, on the adhesion properties of the outer layer (A). The invention preferably carries out the longitudinal stretching process at a temperature in the range from 70 to 95° C., where the heating temperatures are in the range from 70 to 95° C. (preferably below 90° C.) and the stretching temperatures are in the range from 75 to 95° C. The temperature at which the transverse stretching process is carried out can vary relatively widely, and depends on the desired properties of the film, preferably being in the range from 90 to 135° C. The longitudinal stretching ratio is generally in the range from 2.0:1 to 4.5:1, preferably from 2.1:1 to 4.0:1, and particularly preferably from 2.2:1 to 3.6:1. The transverse stretching ratio is generally in the range from 3.0:1 to 5.0:1, preferably from 3.5:1 to 4.5:1.

In the heat-setting process which follows both the simultaneous and the sequential stretching process, the film is kept at a temperature in the range from 150 to 250° C. for a period of about 0.1 to 10 s. The maximum temperature here is preferably >210° C., particularly preferably >230° C., and particularly preferably >240° C. The film is then conventionally cooled and wound up to give a roll of film.

Since a thermal lamination step is used for application of the reverse-side laminate, it has proven advantageous that the longitudinal and transverse shrinkage of the film (measured at 150° C., 30 min) is smaller than 2.5% and particularly smaller than 2%, and in particular <1.8%. Transverse shrinkage is particularly important here and is therefore preferably smaller than 1.2%. Another factor that has proven advantageous, alongside the high maximum temperatures mentioned for the heat-setting process, is at least 1% relaxation of the film during the setting process, preferably at least 3%. In a simultaneous frame, this relaxation preferably takes place longitudinally and transversely, but in a sequential process it preferably takes place only transversely. It is preferable that at least 50% of the total relaxation is achieved at a temperature below 200° C.

The total thickness of the film can be varied widely, as also can the individual thicknesses of the base layer (B) and of the coextruded outer layer (A). The total thickness of the film is preferably in the range from 10 to 600 μm, in particular in the range from 12 to 400 μm, and particularly preferably in the range from 18 to 300 μm, where the minimum thickness of the outer layer (A) is greater than or equal to 0.5 μn, since otherwise the adhesion properties of the outer layer (A) with respect to the encapsulation material used in the solar cells are unsatisfactory. Outer layer thicknesses of more than 6 μm for the coextruded outer layer (A) do not give any further improvement in adhesion properties. It is preferable that the thickness of the coextruded outer layer (A) is in the range from 0.5 to 20 μm, in particular in the range from 2 to 6 μm.

The film of the invention has excellent suitability as a backsheet or backsheet constituent for solar modules. The film of the invention can be used alone as a backsheet for a solar module. However, it can also be used as constituent of a laminated backsheet for solar modules. If the film of the invention is used as constituent of a laminated backsheet for solar modules, it can be laminated together with further films, whereupon the structure of the laminated backsheet is such that the outer layer (A) of the film of the invention is in contact with the EVA embedding layer in the finished module. The structure of the backsheet laminate can have a plurality of film sublayers or layers, and these in particular can also comprise water-vapor-barrier layers (Al foils, Al-metallized polyester films, SiOₓ or AlOₓ, or correspondingly combined layers). The backsheet laminates comprising the films of the invention can use the films usually used in such laminates, examples being those made of PVF or of other fluorinated film materials, or PET, or PEN. Water-vapor-barrier layers have a favorable effect on the long-term electrical yield from the solar module.

In one particularly preferred backsheet-laminate embodiment, the backsheet consists exclusively of the polyester film of the invention. An advantage of this embodiment over fluorinated backsheets is that it can be recycled or incinerated without difficulty.

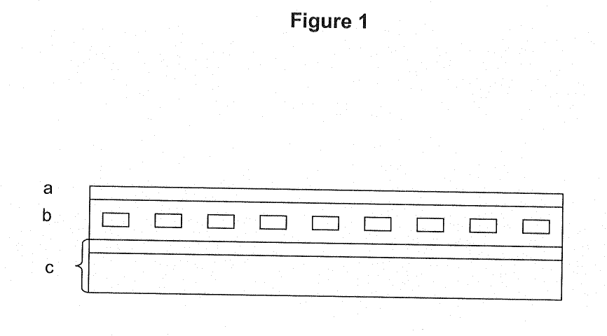

FIG. 1 illustrates an example of a structure of a solar module using the film of the invention, where a) is a highly transparent glass front, b) are Si solar cells embedded in crosslinked EVA, and c) is the backsheet, i.e. the film of the invention.

The test methods used for the purposes of the present invention for characterization of the raw materials and of the films were as follows:

Measurement of Median Diameter d₅₀

Median diameter d₅₀ of particulate additives is determined by means of a laser, by laser scanning in a Malvern MASTERSIZER® (an example of other test equipment being the Horiba LA® 500 or Sympathec HELOS®, which use the same measurement principle). For the test, the specimens are placed in a cell with water, and this is then placed in the test equipment. The dispersion is scanned by a laser and particle size distribution is determined from the signal by comparison with a calibration curve. The test procedure is automatic and also includes mathematical determination of the d₅₀ value. The d₅₀ value is defined here as determined from the (relative) cumulative particle size distribution curve: the intersection of the 50% ordinate value with the cumulative curve gives the desired d₅₀ value (also termed median) on the abscissa axis.

IV Value

The IV value of the polyethylene terephthalate is determined via viscosity measurement at 25° C. on dilute o-chlorobenzene solutions with extrapolation to c=0. Further information on the technique for determining IV is found in Encyclopedia of Polymer Science and Engineering, 1988, vol. 11, pp. 322-323, and Kirk-Othmer, Encyclopedia of Chemical Technology, 4th edition, vol. 21, 1997, pp. 356-358.

### Yellowness Index

Yellowness index is determined via ASTM D1925-70.

### Determination of Adhesion to EVA and Aging Resistance of Adhesion to EVA

Adhesion is determined and assessed as described in EP-A-1 826 826. However, the EVA film used comprises, instead of SOLAR EVA® SC4, the grade SOLAR EVA SC50B, from the successor company Mitsui Chemical Fabro Inc. (JP).

[symbol]

: 20 N/20 mm or more—adhesion is very good
◯: 10 N/20 mm to less than 20 N/20 mm—adhesion is good
Δ: 5 N/20 mm to less than 10 N/20 mm—adhesion is moderate
x: less than 5 N/20 mm—adhesion is poor

In addition to aging after 1000 h at 85° C./85% relative humidity, adhesion after 2000 h at 85° C./85% relative humidity is also assessed, since 1000 h does not simulate the full lifetime of the modules, and therefore adequate adhesion after twice that time is also a requirement.

[symbol]

: 75% or greater retention of adhesion—very good adhesion stability
◯: 50% or less than 75% retention of adhesion-good adhesion stability
Δ: 25% or less than 50% retention of adhesion—moderate adhesion stability
x: less than 25% retention of adhesion—poor adhesion stability

### Weathering Resistance

Weather resistance is determined and assessed as described in EP-A-1 826 826.

[symbol]

: 75% or greater retention of adhesion—very good resistance of adhesion to weathering
◯: 50% or less than 75% retention of adhesion—good resistance of adhesion to weathering
Δ: 25% or less than 50% retention of adhesion—moderate resistance of adhesion to weathering
x: less than 25% retention of adhesion—poor resistance of adhesion to weathering

### Shrinkage

Shrinkage is measured to DIN 40634 at 150° C. with residence time of 15 min.

The examples and comparative examples below provide further explanation of the invention.

### Example 1

| 96% by weight | of pellets made of polyethylene terephthalate | |
|---|---|---|
| | (grade 8610, produced by Invista, USA, | |
| | solid-phase-condensed up to IV = 0.68, | |
| | CEG: 10 mmol/kg) and | |
| 4% by weight | of polyester pellets comprising | |
| | 0.5% by weight | of SiO₂, SYLYSIA ® 320, |
| | | produced by Fuji Sylysia, JP, |
| | | d₅₀ = 2.5 μm, and |
| | 60% by weight | of TiO₂, TI-PURE ® R-104, |
| | | produced by DuPont, USA, kneaded |
| | | in a twin-screw extruder into |
| | 39.5% by weight | of polyester pellets, grade 8610 |

were introduced in a twin-screw extruder with devolatilization for the base layer (B). A mixture made of

| | |
|---|---|
| 12% by weight | of polyethylene terephthalate (grade 8610, |
| | solid-phase-condensed, IV = 0.68) and |
| 88% by weight | of ethylene-methacrylate copolymer |
| | (LOTRYL ® 24 MA 07) |

was likewise introduced in a twin-screw extruder with devolatilization for the outer layer (A). The content of methacrylate in the ethylene-methacrylate copolymer used was 9.4 mol %, corresponding to about 24% by weight, based on the copolymer. The melt index MFI (2.16 kg/190° C.) was 7 g/10 min. The raw materials were respectively melted, homogenized, and devolatilized in the twin-screw extruders. The temperature in the extruder outlet and melt line for the base layer here was set to 284° C., and the temperature in the extruder outlet and melt line for the outer layer (A) was set to 265° C. Layers of the two melt streams were then mutually superposed via coextrusion in a two-layer die and discharged by way of a die lip. The resultant melt film was applied to a cooled casting roll (chill-roll temperature 30° C.) and cooled. The manner of application was such that the free surface of the (B) layer was brought into contact with the chill roll. Simultaneous orientation of the prefilm (stretching temperature 106° C., longitudinal stretching ratio 3.6, transverse stretching ratio 3.8) and subsequent heat-setting (maximum temperature 242° C., 1 s) gave a two-layer biaxially oriented film of AB structure. After the hottest zone of the heat-setting process, the material was relaxed by 3.5% transversely and 2% longitudinally, at a temperature of 185° C. The total thickness of the film was 200 μm, and the thickness of the (A) layer here was 6 μm. Further properties of the film and test results can be found in the “Results” table.

### Example 2

The procedure was analogous to that of Example 1, but the feed for the base layer comprised

| 3% by weight | of epoxidized linseed oil (VIKOFLEX ® 9010, | |
|---|---|---|
| | produced by Arkema, USA), | |
| 1% by weight | of ethylhexyl ester of epoxidized linseed oil fatty | |
| | acids (VIKOFLEX ® 9080), | |
| 92% by weight | of polyethylene terephthalate pellets (grade 8610, | |
| | produced by Invista, USA, solid-phase-condensed up | |
| | to IV = 0.68, CEG: 10 mmol/kg), and | |
| 4% by weight | of polyester pellets comprised of | |
| | 0.5% by weight | of SiO₂, SYLYSIA ® 320, |
| | | produced by Fuji Sylysia, JP, |
| | | d₅₀ = 2.5 μm, and |
| | 60% by weight | of TiO₂, TI-PURE ® R-104, |
| | | produced by DuPont, USA, kneaded |
| | | in a twin-screw extruder into |
| | 39.5% by weight | of polyester pellets, grade 8610. |

### Example 3

The procedure was analogous to that for Example 1, but 35% by weight of regrind was added to the base layer. The other materials fed were

| 61% by weight | of polyethylene terephthalate pellets (grade 8610, | |
|---|---|---|
| | produced by Invista, USA, solid-phase-condensed | |
| | up to IV = 0.68, CEG: 10 mmol/kg), and | |
| 4% by weight | of polyester pellets comprised of | |
| | 0.5% by weight | of SiO₂, SYLYSIA ® 320, |
| | | produced by Fuji Sylysia, JP, |
| | | d₅₀ = 2.5 μm, and |
| | 60% by weight | of TiO₂, TI-PURE ® R-104, |
| | | produced by DuPont, USA, kneaded |
| | | in a twin-screw extruder into |
| | 39.5% by weight | of polyester pellets, grade 8610. |

### Example 4

The procedure was analogous to that for Example 1, but the 96% by weight of solid-phase-condensed polyethylene terephthalate (grade 8610, see above) in the base layer were replaced by the same amount of grade SB62F0 polyester pellets (Advansa, TR).

### Example 5

| 96% by weight | of pellets made of polyethylene terephthalate | |
|---|---|---|
| | (grade 8610, produced by Invista, USA, | |
| | solid-phase-condensed up to IV = 0.68, | |
| | CEG: 10 mmol/kg) and | |
| 4% by weight | of polyester pellets comprised of | |
| | 0.5% by weight | of SiO₂, SYLYSIA ® 320, |
| | | produced by Fuji Sylysia, JP, |
| | | d₅₀ = 2.5 μm, and |
| | 60% by weight | of TiO₂, TI-PURE ® R-104, |
| | | produced by DuPont, USA, kneaded |
| | | in a twin-screw extruder into |
| | 39.5% by weight | of polyester pellets, grade 8610, |

were introduced in a twin-screw extruder with devolatilization for the base layer (B). A mixture made of

| | |
|---|---|
| 12% by weight | of polyethylene terephthalate (grade 8610, |
| | solid-phase-condensed, IV = 0.68) and |
| 88% by weight | of ethylene-methacrylate copolymer |
| | (LOTRYL ® 24 MA 07) |

was likewise introduced in a twin-screw extruder with devolatilization for the outer layer (A). The content of methacrylate in the ethylene-methacrylate copolymer used was 9.4 mol %, corresponding to about 24% by weight, based on the copolymer. The melt index MFI (2.16 kg/190° C.) was 7 g/10 mina The raw materials were respectively melted, homogenized, and devolatilized in the twin-screw extruders. The temperature in the extruder outlet and melt line for the base layer here was set to 284° C., and the temperature in the extruder outlet and melt line for the outer layer (A) was set to 265° C. Layers of the two melt streams were then mutually superposed via coextrusion in a two-layer die and discharged by way of a die lip. The resultant melt film was applied to a cooled casting roll (chill-roll temperature 30° C.) and cooled. The manner of application was such that the free surface of the (B) layer was brought into contact with the chill roll. Simultaneous orientation of the prefilm (stretching temperature 106° C., longitudinal stretching ratio 3.6, transverse stretching ratio 3.8) and subsequent heat-setting (maximum temperature 242° C., 1 s) gave a two-layer biaxially oriented film of AB structure. After the hottest zone of the heat-setting process, the material was relaxed by 3.5% transversely and 2% longitudinally, at a temperature of 185° C. The total thickness of the film was 50 μm, and the thickness of the (A) layer here was 4 μm. Further properties of the film and test results can be found in the “Results” table.

### Example 6

The procedure was analogous to that of Example 5, but the feed for the base layer comprised

| 3% by weight | of epoxidized linseed oil (VIKOFLEX ® 9010, | |
|---|---|---|
| | Arkema, USA), | |
| 1% by weight | of ethylhexyl ester of epoxidized linseed | |
| | oil fatty acids (VIKOFLEX ® 9080), | |
| 92% by weight | of polyethylene terephthalate pellets (grade 8610, | |
| | produced by Invista, USA, | |
| | solid-phase-condensed up to IV = 0.68, | |
| | CEG: 10 mmol/kg), and | |
| 4% by weight | of polyester pellets comprised of | |
| | 0.5% by weight | of SiO₂, SYLYSIA ® 320, |
| | | produced by Fuji Sylysia, JP, |
| | | d₅₀ = 2.5 μm, and |
| | 60% by weight | of TiO₂, TI-PURE ® R-104, |
| | | produced by DuPont, USA, kneaded |
| | | in a twin-screw extruder into |
| | 39.5% by weight | of polyester pellets, grade 8610. |

### Example 7

The procedure was analogous to that for Example 5, but 35% by eight of regrind were added to the base layer. The other materials fed were

| 61% by weight | of polyethylene terephthalate pellets (grade 8610, | |
|---|---|---|
| | produced by Invista, USA, | |
| | solid-phase-condensed up to IV = 0.68, | |
| | CEG: 10 mmol/kg), and | |
| 4% by weight | of polyester pellets comprised of | |
| | 0.5% by weight | of SiO₂, SYLYSIA ® 320, |
| | | produced by Fuji Sylysia, JP, |
| | | d₅₀ = 2.5 μm, and |
| | 60% by weight | of TiO₂, TI-PURE ® R-104, |
| | | produced by DuPont, USA, kneaded |
| | | in a twin-screw extruder into |
| | 39.5% by weight | of polyester pellets, grade 8610. |

### Example 8

The procedure was analogous to that for Example 5, but the 96% by weight of solid-phase-condensed polyethylene terephthalate (grade 8610) in the base layer were replaced by the same amount of grade SB62F0 polyester pellets (Advansa, TR).

### Comparative Example 1

Example 1 of EP-A-1 826 826 was repeated.

### Comparative Example 2

Example 1 of EP-A-1 826 826 was repeated, but 35% by weight of the polyester used ere replaced by 35% by weight of film regrind.

TABLE 1
Results of characterization of Examples and Comparative Examples

| | | Aging resistance of | | | | | |
|---|---|---|---|---|---|---|---|
| | Adhesion to | adhesion to EVA | | Weathering | | Shrinkage | |
| | EVA | 1000 h | 2000 h | resistance | Yellowing | MD | TD |
| Example 1 | [symbol] | [symbol] | [symbol] | [symbol] | A | 0.6 | 0.0 |
| Example 2 | [symbol] | [symbol] | [symbol] | [symbol] | A | 0.7 | 0.0 |
| Example 3 | [symbol] | [symbol] | [symbol] | [symbol] | B | 0.5 | 0.1 |
| Example 4 | [symbol] | [symbol] | [symbol] | [symbol] | A | 0.6 | 0.2 |
| Example 5 | [symbol] | [symbol] | [symbol] | [symbol] | A | 0.5 | 0.0 |
| Example 6 | [symbol] | [symbol] | [symbol] | [symbol] | A | 0.6 | 0.1 |
| Example 7 | [symbol] | [symbol] | [symbol] | [symbol] | B | 0.6 | 0.0 |
| Example 8 | [symbol] | [symbol] | [symbol] | [symbol] | A | 0.7 | 0.2 |
| Comparative Example | [symbol] | [symbol] | ◯ | ◯ | A | not | n.d. |
| 1 (Example 1 of EP | | | | | | determined | |
| 1826 826 A1) | | | | | | | |
| Comparative Example | [symbol] | [symbol] | ◯ | ◯ | C | n.d. | n.d. |
| 2 (Example 1 of EP | | | | | | | |
| 1826 826 A1, but | | | | | | | |
| using 35% by weight | | | | | | | |
| of regrind) | | | | | | | |

Yellowing was assessed visually and divided into the following classes: A = no discernible yellowing, B = discernible yellowing, and C = marked yellowing.

The films of the invention exhibit very good adhesion and aging resistance of adhesion, and weathering resistance, and low yellowness indices and low shrinkage, and have excellent suitability for backsheets and backsheet laminates.

That which is claimed:

1. A coextruded, biaxially oriented polyester film comprising a base layer B and at least one outer layer A,
(i) the base layer B mainly comprising thermoplastic polyester, and
(ii) the outer layer A mainly comprising a mixture comprised of from 50 to 97% by weight of ethylene-acrylate copolymer and from 3 to 50% by weight of polyester,
wherein the proportion of acrylate in the ethylene-acrylate copolymer is from 2.5 to 15 mol %, based on monomers of the copolymer.

2. The polyester film as claimed in claim 1, wherein the base layer B comprises at least 65% by weight of thermoplastic polyester.

3. The polyester film as claimed in claim 1, wherein the base layer B comprises up to 35% by weight, based on the weight of the base layer B, of additives.

4. The polyester film as claimed in claim 3, wherein the additive is a hydrolysis stabilizer.

5. The polyester film as claimed in claim 1, wherein the thermoplastic polyester of the base layer B is a polyester having low carboxy end group content.

6. The polyester film as claimed in claim 1, wherein the thermoplastic polyester of the base layer B comprises up to 25% by weight of ethylene-acrylate copolymer.

7. The polyester film as claimed in claim 1, wherein the outer layer A comprises at least 75% by weight of the mixture comprising ethylene-acrylate copolymer and polyester.

8. The polyester film as claimed in claim 1, wherein the ethylene-acrylate copolymer is a copolymer comprising ethylene and of one or more acrylates.

9. The polyester film as claimed in claim 8, wherein the acrylate has been selected from the group of compounds consisting of ethyl acrylate, ethyl methacrylate, methyl acrylate, methyl methacrylate, propyl acrylate, propyl methacrylate, isopropyl acrylate, isopropyl methacrylate, n-butyl acrylate, n-butyl methacrylate, isobutyl acrylate, isobutyl methacrylate, tert-butyl acrylate, tert-butyl methacrylate, n-hexyl acrylate, n-hexyl methacrylate, n-octyl acrylate, n-octyl methacrylate, 2-octyl acrylate, 2-octyl methacrylate, undecyl acrylate, undecyl methacrylate, octadecyl acrylate, octadecyl methacrylate, dodecyl acrylate, dodecyl methacrylate, 2-ethylhexyl acrylate, 2-ethylhexyl methacrylate, isobornyl acrylate, isobornyl methacrylate, cyclohexyl acrylate, cyclohexyl methacrylate, 2-hydroxyethyl acrylate, and 2-hydroxyethyl methacrylate.

10. The polyester film as claimed in claim 1, wherein the melt index, 2.16 kg/190° C., of the ethylene-acrylate copolymers, measured to DIN EN ISO 1133, is in the range from 0.5 to 50 g/10 min.

11. The polyester film as claimed in claim 1, wherein the outer layer A comprises up to 25% by weight of additives.

12. A process for the production of a polyester film as claimed in claim 1 comprising
coextruding melts corresponding to film layers through a flat-film die,
applying the resultant coextruded film to one or more cooled rolls,
biaxially stretching the cooled film to impart orientation, and
heat-setting the biaxially stretched film and, optionally, corona- or flame-treating a surface layer intended for treatment,
cooling the heat-set film and
winding the cooled heat-set film up.

13. A backsheet for a solar module comprising a film as claimed in claim 1.

14. A film laminate comprising at least one film as claimed in claim 1 and also at least one further film that differs from the film as claimed in claim 1.

15. A solar module comprising a film as claimed in claim 1.
